(19) United States
(12) Patent Application Publication
(10) Pub. No.: US 2013/0316490 A1
(43) Pub. Date: Nov. 28, 2013

(54) SOLAR CELL AND SOLAR CELL PRODUCTION METHOD

(71) Applicants: Yasuhiro Aida, Chuo-ku (JP); Susanne Siebentritt, Belvaux (LU)

(72) Inventors: Yasuhiro Aida, Chuo-ku (JP); Susanne Siebentritt, Belvaux (LU)

(73) Assignees: UNIVERSITE DU LUXEMBOURG, Luxembourg (LU); TDK CORPORATION, Tokyo (JP)

(21) Appl. No.: 13/976,179

(22) PCT Filed: Dec. 28, 2011
(86) PCT No.: PCT/JP2011/080592

§ 371 Date: Aug. 8, 2013

(30) Foreign Application Priority Data
Dec. 28, 2010 (JP) 2010-293658

(51) Int. Cl. H01L 31/18

(52) U.S. Cl. CPC H01L 31/18
USPC 438/95

(57) ABSTRACT

A solar cell according to the present invention includes as a light absorption layer a p-type semiconductor layer having a gradient of X/(In+X) ratios in a film thickness direction and containing an Ib group element, In, an element X, and a VIb group element, wherein a ratio C between values of an X/(In+X) ratio A of an uppermost surface of an p-type semiconductor layer and an X/(In+X) ratio B at a depth at which a smallest X/(In+X) ratio in a film is exhibited is represented by Expressions (1) and (2):

C=A/B (1);

and

1.1<C<1.8 (2).

### TECHNICAL FIELD

The present invention relates to a solar cell and a method for producing the solar cell.

### BACKGROUND ART

A solar cell which uses a thin film semiconductor layer as a light absorption layer is being developed to replace a bulk crystal silicon solar cell which has widely been used. Among the solar cells, a thin film solar cell using a compound semiconductor layer containing the groups Ib, IIIb, and VIb as an absorption layer is expected as a next generation solar cell since the solar cell exhibits high energy conversion efficiency and is less subject to light deterioration. More specifically, a thin film solar cell using CuInSe₂ (hereinafter referred to as CISe) formed of Cu, In, and Se or Cu(In,Ga)Se₂ (hereinafter referred to as CiGSe) in which a part of In belonging to the group IIIb is replaced with Ga is used as the light absorption layer attains the high conversion efficiency. Particularly, it has been reported that the high conversion efficiency is attained by using a vapor deposition method which is called three-stage method (see Non-Patent Publication 1 specified below).

### CITATION LIST

### Patent Literature

[Patent Publication 1] Japanese Patent No. 3249407

### Non Patent Literature

[Non-Patent Publication 1] Prog. Photovolt: Res. Appl. (2008), 16; 235-239
[Non-Patent Publication 2] Solar Energy Materials and Solar Cells 41/42 (1996); 231-246

### SUMMARY OF INVENTION

### Technical Problem

In general p-n junction type solar cells, an open voltage of the solar cell is increased when band gap energy (hereinafter referred to as Eg) of a light absorption layer is increased. In contrast, a short-circuit current density in solar cell characteristics is increased when Eg is reduced. The relationship is a trade-off, and ideal Eg in single p-n junction solar cells is considered to be 1.4 eV to 1.5 eV. For example, in Cu(In,X)(S,Se)₂ (X is an element selected from the group IIIb elements except for In), it is possible to control Eg of the light absorption layer by changing an X/(In+X) ratio or a S/(Se+S) ratio. Further, it has been reported that a degree of a gradient of X/(In+X) ratios in a film thickness direction has great correlation with the solar cell characteristics.

For example, in Patent Document 1, a CIGSe film is formed by stacking films by using a Cu—Ga alloy and an In metal target and then performing a heat treatment under a selenium atmosphere. Also, it is described that it is possible to increase an open voltage by increasing a Ga concentration toward a film bottom (back electrode side) from a film surface (buffer layer side) by adjusting a Ga content of a Cu—Ga alloy target. However, as described above, the increase in open voltage attained by the increase in band gap energy Eg of normal light absorption layer has been well-known, and the short-circuit current density is decreased along with the increase in Eg since the increase in Eg causes a reduction in wavelength at an absorption edge. Though the open voltage is improved by the gradient composition, it is considered that the gradient composition causes a reduction of the short-circuit current density and no improvement or a reduction of the conversion efficiency.

In Non-Patent Publication 2, a double graded band gap which improves the open voltage and enlarges a band gap at a p-n junction boundary surface is formed by forming, in addition to a single graded band gap structure for increasing the band gap energy Eg toward the back electrode direction, a layer having a high Ga concentration in the vicinity of a boundary surface with a buffer layer at a light incidence side of a CiGSe film. With the double graded band gap, it is possible to achieve higher conversion efficiency. Eg of the p-type semiconductor layer is decided by Ga/(In+Ga), and Eg is increased along with an increase in Ga amount. The change in Eg is caused by a change in energy level at a conduction band bottom. In other words, increase in Ga/(In+Ga) of the surface leads to increase of energy level at the conduction band bottom of the film surface portion. It is descried that the structure enables to suppress recombination of light generation carriers in a depletion layer, thereby enabling the improvement in open voltage.

As described above, it is reported that it is possible to attain the improvement in conversion efficiency by using the single graded or double graded band gap structure. However, though a profile is naturally formed by a difference in deposition coefficient or a difference in diffusion coefficient in film between Ga and In in the three-stage method, mutual diffusion of Ga and In in a formed film is inevitable due to the film formation at high temperature, thereby making it difficult to form the Ga/(In+Ga) profile with good reproducibility. Also, an appropriate profile shape itself has not been clarified.

The present invention was accomplished in view of the problems of the conventional technologies and proposes a solar cell having an appropriate X/(In+X) profile (X is an element selected from group IIIb elements except for In) in a depth direction in a p-type semiconductor film which is a light absorption layer for the purpose of attaining good solar cell characteristics as well as a method for obtaining the same. In other words, an object of the present invention is to provide a solar cell having an appropriate X/(In+X) profile (X is an element selected from group IIIb elements except for In) in a depth direction in order to improve an open voltage without a reduction in short-circuit current value in a p-type semiconductor layer which is a light absorption layer.

### Solution to Problem

In order to achieve the above-described object, a solar cell according to the present invention has a gradient of X/(In+X) ratios in a film thickness direction and comprises as a light absorption layer a p-type semiconductor layer containing an Ib group element, an element X, and a VIb group element, wherein a ratio C between values of an X/(In+X) ratio A of an uppermost surface of the p-type semiconductor layer and an X/(In+X) ratio B at a depth at which a smallest X/(In+X) ratio in a film is exhibited is represented by Expressions (1) and (2):

C=A/B (1); and

1.1<C<1.8 (2).

In Expression (1), A represents the X/(In+X) ratio in the uppermost surface (side closest to an n-type layer) of the p-type semiconductor layer, and B represents the X/(In+X) ratio at the depth at which the X/(In+X) ratio is lowest in a depth direction composition distribution analysis of the p-type semiconductor layer. In the present invention, the ratio C=A/B may preferably be 1.40 to 1.80 when the Ib group element, the element X, and the VIb group element are Cu, Ga, and Se respectively.

According to the present invention, as compared to the solar cell provided with the p-type semiconductor layer of the conventional example, it is possible to better suppress occurrence of recombination of light generation carriers in a depletion layer more reliably as well as to effectively increase an open voltage without a reduction in short-circuit current density which is ordinarily caused by an increase in Eg.

In the present invention, the element X to be contained in the p-type semiconductor layer and selected from IIIb groups except for In may preferably be Ga. With such constitution, it is possible to form the p-type semiconductor layer formed of CuInGaSe₂, CuInGaS₂, or the like. With the use of Ga as the element X, it is possible to maintain the band gap energy Eg within a range of from about 1.0 eV to about 2.4 eV which is an optimum for the solar cell light absorption layer.

In the present invention, the Ib group element to be contained in the p-type semiconductor layer may preferably be Cu. With such constitution, it is possible to form the p-type semiconductor layer formed of CuInGaSe₂, CuInGaS₂, or the like.

In the present invention, in a p-type semiconductor formation step, it is preferable to form the p-type semiconductor by: a first film formation step comprising vapor deposition of In, an element X selected from IIIb group elements except for In, and a VI group element; a second film formation step comprising vapor deposition of an Ib group element and a VI group element; and a third film formation step comprising vapor deposition of In, the element X selected from the IIIb group elements except for In. Further, it is preferable that a ratio P₃=Pₓ₃/P_{In3} between flux amounts of In and the element X in the third step is higher than a flux ratio P₁=Pₓ₁/P_{In1} in the first step.

In the present invention, a value of P₃/P₁ which is a ratio between the flux ratios P₁=Pₓ₁/P_{In1} and P₃=Pₓ₃/P_{In3} between In and the element X in the first step and the third step may preferably be 1.1 to 1.8. Further, the effect becomes more prominent when the value is larger within the above-specified range. In the present invention, the ratio P₃=Pₓ₃/P_{In3} may preferably be 1.35 to 1.80 when the Ib group element, the element X, and the VIb group element are Cu, Ga, and Se respectively.

In the present invention, the element X selected from the IIIb group elements except for In, which is used as a deposition source in the p-type semiconductor formation step, may preferably be Ga. With such constitution, the effect of the present invention becomes prominent.

In the present invention, the Ib group element which is used as a deposition source in the p-type semiconductor formation step may preferably be Cu. With the use of Cu, a liquid phase represented by CuSe or CuS is generated on a film surface during the film formation to accelerate crystal growth. Thus, a defect level in the film is reduced to reduce recombination probability of light generation carriers in the absorption layer, thereby improving conversion efficiency.

In the present invention, a method comprising a step of stacking a precursor layer by performing sputtering by using a first target containing one of the IIIb group elements except for In in addition to Cu and a second target containing In and a heat treatment step of heating the precursor under an atmosphere containing a VIb group element may be employed in the p-type semiconductor formation step.

In the present invention, a position at which the X/(In+X) ratio is lowest in the depth direction may preferably be between 0.1 μm and 1.0 μm from a surface. Since the depletion layer of a p-n junction in the solar cell is generally positioned within the above-specified range of depth, it is possible to reduce the carrier recombination in the depletion layer by forming a smallest X concentration point within the above-specified range and increasing an amount of the element X on the surface, thereby attaining improvement in conversion efficiency.

### Advantageous Effects of Invention

According to the present invention, it is possible to provide a solar cell which is capable of increasing an open voltage without deterioration of a short-circuit current as compared to conventional solar cells as well as a production method for the solar cell.

### BRIEF DESCRIPTION OF DRAWINGS

FIG. 1 is a sectional view schematically showing a solar cell according to one embodiment of the present invention.

FIG. 2 is a diagram schematically showing a depth direction composition ratio profile of Ga/(In+Ga) of a light absorption layer in a Cu(In,Ga)(S,Se)₂ solar cell according to the embodiment of the present invention. A point A represents a GA/(In+Ga) ratio on an uppermost surface of the light absorption layer, and a point B represents a depth at which the Ga/(In+Ga) ratio is smallest in the light absorption layer.

### DESCRIPTION OF EMBODIMENTS

Hereinafter, one preferred mode of embodiment of the present invention will be described with reference to the accompanying drawings. In the drawings, identical or similar elements are denoted by an identical reference numeral. Also, a position relationship in terms of up, down, left, and right are as shown in the drawings. Also, in the case where a descriptions overlaps, the overlapping description is not repeated.

(Solar Cell)

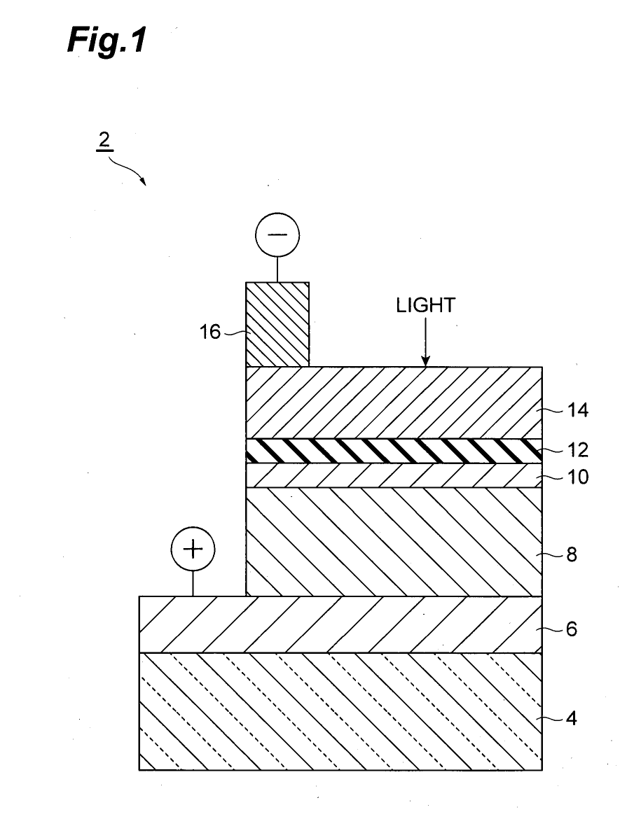

As shown in FIG. 1, a solar cell 2 according to the present embodiment is a thin film solar cell provided with a soda lime glass 4 (blue plate glass), a back electrode layer 6 formed on the soda lime glass 4, a p-type light absorption layer 8 formed on the back electrode layer 6, an n-type buffer layer 10 formed on the p-type light absorption layer 8, a semi-insulation layer 12 formed on the n-type buffer layer 10, a window layer (transparent electroconductive layer) 14 formed on the semi-insulation layer 12, and an upper electrode (extraction electrode) 16 formed on the window layer 14.

The p-type light absorption layer 8 is a p-type compound semiconductor layer formed of Cu, an Ib group element such as Ag or Au, In, an element X selected from IIIb group elements except for In, and a VIb element such as O, S, Se, or Te.

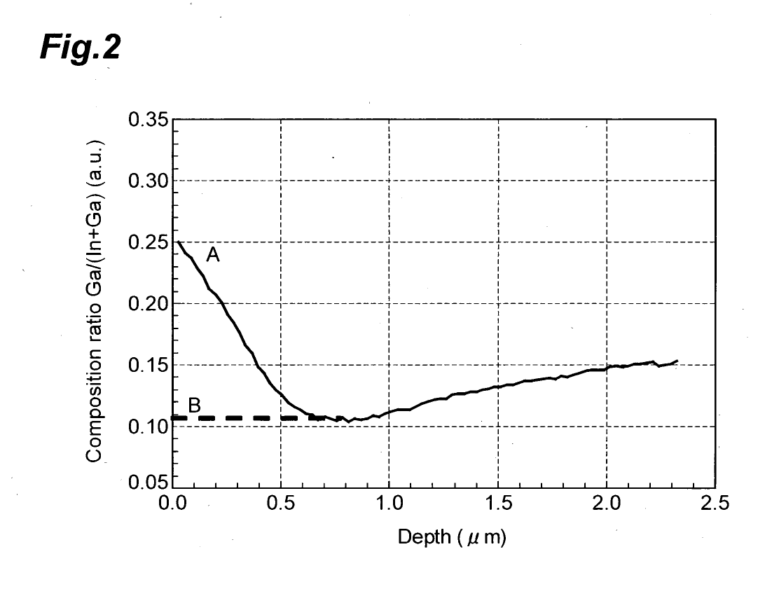

The p-type light absorption layer 8 has a concentrating gradient of X/(In+X) ratios shown in FIG. 2 in a film thickness direction, and a value C=A/B which is a ratio between an X/(In+X) composition ratio A of a p-type light absorption layer surface (at a side of n-type buffer layer 10) and an X/(In+X) composition ratio B at a depth at which the X/(In+X) ratio is smallest in the film is 1.1 to 1.8. Thus, it is possible to effectively reduce recombination of light generation carriers in a depletion layer, thereby enabling to increase an open voltage. The ratio C=A/B may preferably be 1.40 to 1.80 when the Ib group element, the element X, and the VIb group element are Cu, Ga, and Se respectively.

In the case where the value of C is less than 1.1, the light generation carriers easily recombine in the depletion layer to reduce the open voltage.

In the case where the value of C is larger than 1.8, a defect level serving as a recombination center is formed in the vicinity of a p-n junction surface boundary by a reduction in crystallinity which is caused by an increase in concentration of the element X in the p-type light absorption layer 8 in the vicinity of the p-n junction surface boundary, and the light generation carriers easily recombine on the junction surface boundary, thereby reducing the open voltage.

In the present embodiment, the element X selected from the IIIb group elements except for In in the p-type light absorption layer 8 may preferably be Ga. With such constitution, it is possible to maintain band gap energy Eg within a range of from about 1.0 eV to about 2.4 eV, which is optimum for solar cell light absorption layers. With such constitution, the effect of the present invention becomes prominent.

In the present embodiment, the Ib group element in the p-type light absorption layer 8 may preferably be Cu. Also, a composition of the Ib group element may preferably be such that a Cu content in the p-type light absorption layer is 21 at % to 24.9 at %. With such constitution, the effect of the present invention becomes prominent.

In the case where the Cu content is less than 21 at %, a hole concentration is remarkably reduced, and the p-type light absorption layer 8 is disabled to function as a p-type semiconductor, or the p-type light absorption layer 8 exhibits characteristics of an n-type semiconductor to be disabled to function as a solar cell element.

In the case where the Cu content is larger than 24.9 at %, the p-type light absorption layer 8 does not become a single phase film but becomes a film containing a different phase having high electroconductivity, which is represented by Cu₂Se, CuSe, Cu₂S, CuS, or the like. A solar cell element having the p-type semiconductor layer 8 including the high electroconductivity phase is remarkably reduced in resistance, and the back electrode, the n-type layer, and the window layer are short-circuited via the p-type semiconductor layer 8 having the high electroconductivity phase to disable the solar cell element to function as a solar cell.

In the present embodiment, the VIb element in the p-type light absorption layer 8 may preferably be at least one species selected from Se and S. With such constitution, the effect of the present invention becomes prominent.

In the present embodiment, a position at which the X/(In+X) ratio is lowest in the depth direction may preferably be between 0.1 μm and 1.0 gm from a surface of the p-type light absorption layer 8. Since the depletion layer of the p-n junction in the solar cell element is generally positioned within the above-specified range, it is possible to reduce the carrier recombination in the depletion layer by forming a point at which the X/(In+X) ratio is lowest within the above-specified range and increasing an amount of the element X on the surface, thereby attaining improvement in conversion efficiency.

(Solar Cell Production Method)

In the present embodiment, the back electrode layer 6 is firstly formed on the soda lime glass 4. The back electrode layer 6 typically is a metal layer formed of Mo. Examples of a method for forming the back electrode layer 6 include sputtering of a Mo target and the like.

In the present embodiment, after forming the back electrode layer 6 on the soda lime glass 4, the p-type light absorption layer 8 is formed on the back electrode layer 6 by a vapor deposition method.

A step of forming the p-type light absorption layer 8 may preferably include a first step of performing simultaneous vapor deposition of In, the element X selected from the IIIb group elements except for In, and the VIb group element; a second step of performing simultaneous vapor deposition of the Ib group element such as Cu, Ag, or Au and the VIb group element; and a third step of performing simultaneous vapor deposition of In, the element X selected from IIIb group elements except for In, and the VI group element. Particularly, it is preferable that a ratio P₃=Pₓ₃/P_{In3} between flux amounts of In and the element X in the third step is higher than a ratio P₁=Pₓ₁/P_{In1} between flux amounts of In and the element X in the first step.

A value of P₃/P₁ which is a ratio between the flux ratios P₁=Pₓ₁/P_{In1} and P₃=Pₓ₃/P_{In3} between In and the element X in the first step and the third step may preferably be 1.1 to 1.8. Further, the effect becomes more prominent when the value is larger within the above-specified range. The ratio P₃=Pₓ₃/P_{In3} may preferably be 1.35 to 1.80 when the Ib group element, the element X, and the VIb group element are Cu, Ga, and Se respectively.

In the step of forming the p-type light absorption layer 8 by the vapor deposition method, it is preferable to use Ga as the element X which is one of vapor deposition sources and selected from the IIIb group elements except for In. With such constitution, it is possible to maintain band gap energy Eg within a range of from about 1.0 eV to about 2.4 eV which is optimum for solar cell light absorption layers.

In the step of forming the p-type light absorption layer 8 by the vapor deposition method, a temperature of a substrate may preferably be maintained to 200° C. to 550° C., more preferably to 400° C. to 550° C. As used herein, the term “substrate” means an object which undergoes the vapor deposition in the vapor deposition method, and the substrate in the step of forming the p-type light absorption layer 8 means the soda lime glass 4 and the back electrode layer 6.

In the case where the temperature of the substrate is too low, there is a tendency that the p-type light absorption layer 8 is easily detached from the back electrode layer 6. Also, since the crystal growth is hampered by the low temperature, a defect level is generated in the film to cause easy recombination in the absorption layer, and transport characteristics of the light generation carriers are deteriorated to reduce the conversion efficiency. In contrast, in the case where the temperature of the substrate is too high, the soda lime glass 4, the back electrode layer 6, or the p-type semiconductor layer 8 is softened to be easily deformed. It is possible to suppress these tendencies by maintaining the substrate temperature within the above-specified range.

As the production step for the p-type light absorption layer 8, a step including a step of stacking a precursor layer by performing sputtering by using a first target containing the element X selected from the IIIb group elements except for In in addition to Cu and a second target containing In and a heat treatment step of heating the precursor under an atmosphere containing a VIb group element may be employed. With this method, it is possible to relatively easily form a film having a uniform film thickness and composition on a large area.

The element X to be contained in the first target may preferably be Ga. By using Ga as the element X, it is possible to maintain the band gap energy Eg within a range of from about 1.0 eV to about 2.4 eV, which is optimum for solar cell light absorption layers.

A temperature in the heat treatment step may preferably be 200° C. to 550° C., more preferably 400° C. to 550° C.

In the case where the temperature of the substrate is too low, mutual diffusion of the precursor layer is not accelerate due to the low temperature to cause a nonuniform film composition, and the crystal growth is hampered due to the low temperature. Accordingly, a defect is formed in the film to cause easy recombination in the absorption layer, and transport characteristics of the light generation carriers are deteriorated, thereby reducing the conversion efficiency. In contrast, in the case where the temperature of the substrate is too high, the soda lime glass 4, the back electrode layer 6, or the p-type semiconductor layer 8 is softened to be easily deformed. It is possible to suppress these tendencies by maintaining the substrate temperature in the heat treatment within the above-specified range.

After the formation of the p-type light absorption layer 8, the n-type buffer layer 10 is formed on the p-type light absorption layer 8. Examples of the n-type buffer layer 10 include a CdS layer, a Zn(S,O,OH) layer, a ZnMgO layer, a Zn(Ox,S₁₋ₓ) layer (X is a positive real number less than 1), and the like. It is possible to form the CdS layer and the Zn(S,O,OH) layer by chemical bath deposition. It is possible to form the ZnMgO layer by chemical vapor deposition such as MOCVD (Metal Organic Chemical Vapor Deposition) or sputtering. It is possible to form the Zn(Oₓ,S₁₋ₓ) layer by ALD (Atomic layer Deposition) or the like.

After the formation of the n-type buffer layer 10, the semi-insulation layer 12 is formed on the n-type buffer layer 10, and the window layer 14 is formed on the semi-insulation layer 12, followed by formation of the upper electrode 16 on the window layer 14.

Examples of the semi-insulation layer 12 include a ZnO layer, a ZnMgO layer, and the like.

Examples of the window layer 14 include ZnO:Al, ZnO:B, ZnO:Ga, ITO, and the like.

It is possible to form the semi-insulation layer 12 and the window layer 14 by chemical vapor deposition such as MOCVD or sputtering.

The upper electrode 16 is formed of a metal such as Al or Ni, for example. It is possible to form the upper electrode 16 by resistive heating vapor deposition, electron beam vapor deposition, or sputtering. Thus, the thin film solar cell 2 is obtained. An antireflection layer may be formed on the window layer 14. Examples of the antireflection layer include MgF₂, TiO₂, SiO₂, and the like. It is possible to form the window layer 14 by resistive heating vapor deposition, electron beam vapor deposition, or sputtering.

Though one preferred mode of embodiment of the present invention is described in detail above, the present invention is not limited to the above-described embodiment. For example, the p-type light absorption layer 8 may be formed by sputtering, printing, electrocrystallization, gas phase selenization, solid phase selenization, or a combined method thereof. Thus, it is possible to form the solar cell 2 according to the above-described embodiment.

### EXAMPLES

Hereinafter, the present invention will be described in more details based on examples and comparative examples, but the present invention is not limited to the examples.

### Example 1

After washing and drying a blue plate glass having a length of 10 cm, a width of 10 cm, and a thickness of 1 mm, a back electrode in the form of a film formed solely of Mo was formed on the blue plate glass by sputtering. A film thickness of the back electrode was 1 μm.

Subsequently, a p-type semiconductor film formation was performed by employing a three-stage method and using a physical vapor deposition (hereinafter abbreviated to PVD) device. The three-stage method means a method of performing vapor deposition of In, Ga, and Se at a first stage, vapor deposition of Cu and Se at a second stage, and vapor deposition of In, Ga, and Se at a third stage. In advance of start of the film formation, temperatures of K-cells which were vapor deposition sources were set in order to obtain desired fluxes of the elements, and relationships between the temperatures and the fluxes were measured. Thus, it is possible to appropriately set the fluxes to the desired values during the film formation.

The fluxes for the first stage were as follows.

In: 5.0×10⁻⁷ torr

Ga: 5.0×10⁻⁸ torr

Se: 5.0×10⁻⁶ torr

The fluxes for the second stage were as follows.

Cu: 1.0×10⁻⁷ torr

Se: 5.0×10⁻⁶ torr

The fluxes for the third stage were as follows.

In: 5.0×10⁻⁷ torr

Ga: 9.0×10⁻⁸ torr

Se: 5.0×10⁻⁶ torr

The back electrode formed on the blue plate glass was placed in a chamber of the PVD device, and the chamber was evacuated. A pressure to be attained in the vacuum device was set to 1.0×10⁻⁸ torr.

In Example 1, “substrate” is an object which undergoes the vapor deposition in each of the vapor deposition steps.

In the first stage, the substrate was heated to 300° C., and shutters of the K-cells of In, Ga, and Se were opened, followed by vapor deposition of In, Ga, and Se on the substrate. At a time point when a layer having a thickness of about 1μm is formed on the substrate by the vapor deposition, the shutters of the K-cells of In and Ga were closed to finish the vapor deposition of In and Ga. Supply of Se was continued. After termination of the first stage, the temperatures of the K-cells of In and Ga were changed in order to attain the fluxes for the third stage.

In the second stage, after heating the substrate to 520° C., the shutter of the K-cell of Cu was opened, and Se and Cu were vapor-deposited on the substrate. In the second stage and the third stage described later in this specification, power for heating the substrate was kept constant, and feedback of a temperature value with respect to the power was not performed. Also, in the second stage, a surface temperature of the substrate was monitored by using a radiation thermometer, and the deposition of Cu was terminated by closing the shutter of the K-cell of Cu upon confirmation of start of lowering of the temperature after a temperature rise of the substrate was stopped. Supply of Se was continued. At a time point when the vapor deposition of the second stage was terminated, the thickness of the layer formed on the substrate was increased by about 0.8 μm as compared to the time point when the vapor deposition of the first stage was terminated.

In the third stage, the shutters of the K-cells of In and Ga were opened again, and In, Ga, and Se were vapor-deposited on the substrate in the same manner as in the first stage. At a time point when the thickness of the layer formed on the substrate was increased by about 0.2 μm from the time point when the vapor deposition of the third stage was started, the shutters of the K-cells of In and Ga were closed to terminate the vapor deposition of the third stage. After cooling the substrate to 300° C., the shutter of the K-cell of Se was closed to terminate the film formation of the p-type semiconductor layer.

A depth profile of the p-type semiconductor layer in a Ga/(In+Ga) film thickness direction was measured and analyzed by Auger electron spectroscopy (AES). A ratio C between a Ga/(In+Ga) ratio A on an uppermost surface of the p-type semiconductor layer and a Ga/(In+Ga) ratio B at a depth exhibiting a smallest Ga/(In+Ga) ratio in the film was 1.288.

After the formation of the p-type semiconductor layer, an n-type CdS buffer layer having a thickness of 50 nm was formed on the p-type semiconductor layer by chemical bath deposition (CBD).

After the formation of the n-type buffer layer, an i-ZnO layer (semi-insulation layer) having a thickness of 50 nm was formed on the n-type buffer layer. Subsequently, a ZnO:Al layer (window layer) having a thickness of 1 μm was formed on the i-ZnO layer.

An collecting electrode (upper electrode) formed of Al and having a thickness of 1 μm was formed on the ZnO:Al layer. Each of the i-ZnO layer, the ZnO:Al layer, and the collecting electrode were formed by sputtering. Thus, a thin film solar cell of Example 1 was obtained.

### Examples 2 to 5 and Comparative Examples 1 and 2

In each of p-type semiconductor layer film formation steps, the third stage fluxes were set to values shown in Table 1.

Solar cells of Examples 2 to 5 and Comparative Examples 1 and 2 were produced in the same manner as in Example 1 except for the above-specified matters.

A depth profile of each of the p-type semiconductor layers in a Ga/(In+Ga) film thickness direction was measured and analyzed by Auger electron spectroscopy (AES). Ratios each of which is C=A/B between a Ga/(In+Ga) ratio A on an uppermost surface of each of the p-type semiconductor layers and a Ga/(In+Ga) ratio B at a depth exhibiting a smallest Ga/(In+Ga) ratio in the film are shown in Table 1.

TABLE 1

| | | | | | | | | AES |
|---|---|---|---|---|---|---|---|---|
| | First stage flux | | | Third stage flux | | | | analysis |
| | P_{In1} | P_{Ga1} | P₁ | P_{In3} | P_{Ga3} | P₃ | | value |
| | (torr) | (torr) | (=P_{Ga1}/P_{In1}) | (torr) | (torr) | (=P_{Ga3}/P_{In3}) | P₃/P₁ | C = A/B |
| Comp. | 5.00E−07 | 8.00E−08 | 0.160 | 5.00E−07 | 7.90E−08 | 0.158 | 0.988 | 0.974 |
| Ex. 1 | | | | | | | | |
| Ex. 1 | 5.00E−07 | 8.00E−08 | 0.160 | 5.00E−07 | 9.00E−08 | 0.180 | 1.125 | 1.288 |
| Ex. 2 | 5.00E−07 | 8.00E−08 | 0.160 | 5.00E−07 | 9.80E−08 | 0.196 | 1.225 | 1.122 |
| Ex. 3 | 5.00E−07 | 8.00E−08 | 0.160 | 5.00E−07 | 1.10E−07 | 0.220 | 1.375 | 1.462 |
| Ex. 4 | 5.00E−07 | 8.00E−08 | 0.160 | 5.00E−07 | 1.24E−07 | 0.248 | 1.550 | 1.725 |
| Ex. 5 | 5.00E−07 | 8.00E−08 | 0.160 | 5.00E−07 | 1.31E−07 | 0.262 | 1.638 | 1.561 |
| Comp. | 5.00E−07 | 8.00E−08 | 0.160 | 5.00E−07 | 1.58E−07 | 0.316 | 1.975 | 1.950 |
| Ex. 2 | | | | | | | | |

### Example 6

A back electrode was formed in the same manner as in Example 1.

Subsequently, a p-type semiconductor film formation was performed by employing a three-stage method and using a physical vapor deposition (hereinafter abbreviated to PVD) device. The three-stage method means a method of performing vapor deposition of In, Ga, and S at a first stage, vapor deposition of Cu and S at a second stage, and vapor deposition of In, Ga, and S at a third stage. In advance of start of the film formation, temperatures of K-cells which were vapor deposition sources were set in order to obtain desired fluxes of the elements, and relationships between the temperatures and the fluxes were measured. Thus, it is possible to appropriately set the fluxes to the desired values during the film formation.

The fluxes for the first stage were as follows.

In: 5.0×10⁻⁷ torr

Ga: 8.0×10⁻⁸ torr

S: 5.0×10⁻⁶ torr

The fluxes for the second stage were as follows.

Cu: 1.0×10⁻⁷ torr

S: 5.0×10⁻⁶ torr

The fluxes for the third stage were as follows.

In: 5.0×10⁻⁷ torr

Ga: 8.9×10⁻⁸ torr

S: 5.0×10⁻⁶ torr

The back electrode formed on the blue plate glass was placed in a chamber of the PVD device, and the chamber was evacuated. A pressure to be attained in the vacuum device was set to 1.0×10⁻⁸ torr.

In Example 6, “substrate” is an object which undergoes the vapor deposition in each of the vapor deposition steps.

In the first stage, the substrate was heated to 300° C., and shutters of the K-cells of In, Ga, and S were opened, followed by vapor deposition of In, Ga, and S on the substrate. At a time point when a layer having a thickness of about 1 μm is formed on the substrate by the vapor deposition, the shutters of the K-cells of In and Ga were closed to finish the vapor deposition of In and Ga. Supply of S was continued. After termination of the first stage, the temperatures of the K-cells of In and Ga were changed in order to attain the fluxes for the third stage.

In the second stage, after heating the substrate to 520° C., the shutter of the K-cell of Cu was opened, and S and Cu were vapor-deposited on the substrate. In the second stage and the third stage described later in this specification, power for heating the substrate was kept constant, and feedback of a temperature value with respect to the power was not performed. Also, in the second stage, a surface temperature of the substrate was monitored by using a radiation thermometer, and the deposition of Cu was terminated by closing the shutter of the K-cell of Cu upon confirmation of start of lowering of the temperature after a temperature rise of the substrate was stopped. Supply of S was continued. At a time point when the vapor deposition of the second stage was terminated, the thickness of the layer formed on the substrate was increased by about 0.8 μm as compared to the time point when the vapor deposition of the first stage was terminated.

In the third stage, the shutters of the K-cells of In and Ga were opened again, and In, Ga, and S were vapor-deposited on the substrate in the same manner as in the first stage. At a time point when the thickness of the layer formed on the substrate was increased by about 0.2 μm from the time point when the vapor deposition of the third stage was started, the shutters of the K-cells of In and Ga were closed to terminate the vapor deposition of the third stage. After cooling the substrate to 300° C., the shutter of the K-cell of S was closed to terminate the film formation of the p-type semiconductor layer.

A depth profile of the p-type semiconductor layer in a Ga/(In+Ga) film thickness direction was measured and analyzed by

Auger electron spectroscopy (AES). A ratio C between a Ga/(In+Ga) ratio A on an uppermost surface of the p-type semiconductor layer and a Ga/(In+Ga) ratio B at a depth exhibiting a smallest Ga/(In+Ga) ratio in the film was 1.190.

A solar cell of Example 6 was created in the same manner as in Example 1 except for the above-described matters.

### Examples 7 and 8 and Comparative Examples 3 and 4

In each of p-type semiconductor layer film formation steps, third stage fluxes were set to values shown in Table 2.

Solar cells of Example 7, Example 8, Comparative Example 3, and Comparative Example 4 were created in the same manner as in Example 6 except for the above-described matters.

A depth profile of each of the p-type semiconductor layers in a Ga/(In+Ga) film thickness direction was measured and analyzed by Auger electron spectroscopy (AES). Ratios each of which is C=A/B between a Ga/(In+Ga) ratio A on an uppermost surface of each of the p-type semiconductor layers and a Ga/(In+Ga) ratio B at a depth exhibiting a smallest Ga/(In+Ga) ratio in the film are shown in Table 2.

TABLE 2

| | | | | | | | | AES |
|---|---|---|---|---|---|---|---|---|
| | First stage flux | | | Third stage flux | | | | analysis |
| | P_{In1} | P_{Ga1} | P₁ | P_{In3} | P_{Ga3} | P₃ | | value |
| | (torr) | (torr) | (=P_{Ga1}/P_{In1}) | (torr) | (torr) | (=P_{Ga3}/P_{In3}) | P₃/P₁ | C = A/B |
| Comp. | 5.00E−07 | 8.00E−08 | 0.16 | 5.00E−07 | 7.80E−08 | 0.156 | 0.975 | 1.030 |
| Ex. 3 | | | | | | | | |
| Ex. 6 | 5.00E−07 | 8.00E−08 | 0.16 | 5.00E−07 | 8.90E−08 | 0.178 | 1.113 | 1.190 |
| Ex. 7 | 5.00E−07 | 8.00E−08 | 0.16 | 5.00E−07 | 1.20E−07 | 0.240 | 1.500 | 1.570 |
| Ex. 8 | 5.00E−07 | 8.00E−08 | 0.16 | 5.00E−07 | 1.40E−07 | 0.280 | 1.750 | 1.800 |
| Comp. | 5.00E−07 | 8.00E−08 | 0.16 | 5.00E−07 | 1.57E−07 | 0.314 | 1.963 | 1.999 |
| Ex. 4 | | | | | | | | |

### Example 9

A back electrode was formed in the same manner as in Example 1.

Subsequently, a p-type semiconductor film formation was performed by employing a three-stage method and using a physical vapor deposition (hereinafter abbreviated to PVD) device. The three-stage method means a method of performing vapor deposition of In, Ga, and Se at a first stage, vapor deposition of Ag and Se at a second stage, and vapor deposition of In, Ga, and Se at a third stage. In advance of start of the film formation, temperatures of K-cells which were vapor deposition sources were set in order to obtain desired fluxes of the elements, and relationships between the temperatures and the fluxes were measured. Thus, it is possible to appropriately set the fluxes to the desired values during the film formation.

The fluxes for the first stage were as follows.

In: 5.0×10⁻⁷ torr

Ga: 1.3×10⁻⁷ torr

Se: 5.0×10⁻⁶ torr

The fluxes for the second stage were as follows.

Ag: 1.0×10⁻⁷ torr

Se: 5.0×10⁻⁶ torr

The fluxes for the third stage were as follows.

In: 5.0×10⁻⁷ torr

Ga: 1.51×10⁻⁸ torr

Se: 5.0×10⁻⁶ torr

The back electrode formed on the blue plate glass was placed in a chamber of the PVD device, and the chamber was evacuated. A pressure to be attained in the vacuum device was set to 1.0×10⁻⁸ torr.

In Example 9, “substrate” is an object which undergoes the vapor deposition in each of the vapor deposition steps.

In the first stage, the substrate was heated to 300° C., and shutters of the K-cells of In, Ga, and S were opened, followed by vapor deposition of In, Ga, and S on the substrate. At a time point when a layer having a thickness of about 1 gm is formed on the back electrode by the vapor deposition, the shutters of the K-cells of In and Ga were closed to finish the vapor deposition of In and Ga. Supply of S was continued. After termination of the first stage, the temperatures of the K-cells of In and Ga were changed in order to attain the fluxes for the third stage.

In the second stage, after heating the substrate to 520° C., the shutter of the K-cell of Ag was opened, and Se and Ag were vapor-deposited on the substrate. In the second stage and the third stage described later in this specification, power for heating the substrate was kept constant, and feedback of a temperature value with respect to the power was not performed. Also, in the second stage, a surface temperature of the substrate was monitored by using a radiation thermometer, and the vapor deposition of Ag was terminated by closing the shutter of the K-cell of Ag upon confirmation of start of lowering of the temperature after a temperature rise of the substrate was stopped. Supply of Se was continued. At a time point when the vapor deposition of the second stage was terminated, the thickness of the layer formed on the substrate was increased by about 0.8 μm as compared to the time point when the vapor deposition of the first stage was terminated.

In the third stage, the shutters of the K-cells of In and Ga were opened again, and In, Ga, and Se were vapor-deposited on the substrate in the same manner as in the first stage. At a time point when the thickness of the layer formed on the substrate was increased by about 0.2 μm from the time point when the vapor deposition of the third stage was started, the shutters of the K-cells of In and Ga were closed to terminate the vapor deposition of the third stage. After cooling the substrate to 300° C., the shutter of the K-cell of Se was closed to terminate the film formation of the p-type semiconductor layer.

A depth profile of the p-type semiconductor layer in a Ga/(In+Ga) film thickness direction was measured and analyzed by Auger electron spectroscopy (AES). A ratio C between a Ga/(In+Ga) ratio A on an uppermost surface of the p-type semiconductor layer and a Ga/(In+Ga) ratio B at a depth exhibiting a smallest Ga/(In+Ga) ratio in the film was 1.210.

A solar cell of Example 9 was created in the same manner as in Example 1 except for the above-described matters.

### Examples 10 and 11 and Comparative Examples 5 and 6

In each of p-type semiconductor layer film formation steps, third stage fluxes were set to values shown in Table 3.

Solar cells of Example 10, Example 11, Comparative Example 3, and Comparative Example 4 were created in the same manner as in Example 9 except for the above-described matters.

A depth profile of each of the p-type semiconductor layers in a Ga/(In+Ga) film thickness direction was measured and analyzed by Auger electron spectroscopy (AES). Ratios each of which is C=A/B between a Ga/(In+Ga) ratio A on an uppermost surface of each of the p-type semiconductor layers and a Ga/(In+Ga) ratio B at a depth exhibiting a smallest Ga/(In+Ga) ratio in the film are shown in Table 3.

TABLE 3

| | | | | | | | | AES |
|---|---|---|---|---|---|---|---|---|
| | First stage flux | | | Third stage flux | | | | analysis |
| | P_{In1} | P_{Ga1} | P₁ | P_{In3} | P_{Ga3} | P₃ | | value |
| | (torr) | (torr) | (=P_{Ga1}/P_{In1}) | (torr) | (torr) | (=P_{Ga3}/P_{In3}) | P₃/P₁ | C = A/B |
| Comp. | 5.00E−07 | 1.30E−07 | 0.26 | 5.00E−07 | 1.21E−07 | 0.242 | 0.931 | 0.95 |
| Ex. 5 | | | | | | | | |
| Ex. 9 | 5.00E−07 | 1.30E−07 | 0.26 | 5.00E−07 | 1.51E−07 | 0.302 | 1.162 | 1.21 |
| Ex. 10 | 5.00E−07 | 1.30E−07 | 0.26 | 5.00E−07 | 2.00E−07 | 0.400 | 1.538 | 1.51 |
| Ex. 11 | 5.00E−07 | 1.30E−07 | 0.26 | 5.00E−07 | 2.30E−07 | 0.460 | 1.769 | 1.79 |
| Comp. | 5.00E−07 | 1.30E−07 | 0.26 | 5.00E−07 | 2.60E−07 | 0.520 | 2.000 | 1.99 |
| Ex. 6 | | | | | | | | |

### Example 12

A back electrode was formed in the same manner as in Example 1.

Subsequently, a p-type semiconductor film formation was performed by employing a three-stage method and using a physical vapor deposition (hereinafter abbreviated to PVD) device. The three-stage method means a method of performing vapor deposition of In, Al, and Se at a first stage, vapor deposition of Cu and Se at a second stage, and vapor deposition of In, Al, and Se at a third stage. In advance of start of the film formation, temperatures of K-cells which were vapor deposition sources were set in order to obtain desired fluxes of the elements, and relationships between the temperatures and the fluxes were measured. Thus, it is possible to appropriately set the fluxes to the desired values during the film formation.

The fluxes for the first stage were as follows.

In: 5.0×10⁻⁷ torr

Al: 5.0×10⁻⁸ torr

Se: 5.0×10⁻⁶ torr

The fluxes for the second stage were as follows.

Cu: 1.0×10⁻⁷ torr

Se: 5.0×10⁻⁶ torr

The fluxes for the third stage were as follows.

In: 5.0×10⁻⁷ torr

Al: 5.75×10″⁸ torr

Se: 5.0×10⁻⁶ torr

The back electrode formed on the blue plate glass was placed in a chamber of the PVD device, and the chamber was evacuated. A pressure to be attained in the vacuum device was set to 1.0×10⁻⁸ torr.

In Example 12, “substrate” is an object which undergoes the vapor deposition in each of the vapor deposition steps.

In the first stage, the substrate was heated to 300° C., and shutters of the K-cells of In, Al, and Se were opened, followed by vapor deposition of In, Al, and Se on the substrate. At a time point when a layer having a thickness of about 1 μm is formed on the substrate by the vapor deposition, the shutters of the K-cells of In and Al were closed to finish the vapor deposition of In and Al. Supply of Se was continued. After termination of the first stage, the temperatures of the K-cells of In and Al were changed in order to attain the fluxes for the third stage.

In the second stage, after heating the substrate to 520° C., the shutter of the K-cell of Cu was opened, and Se and Cu were vapor-deposited on the substrate. In the second stage and the third stage described later in this specification, power for heating the substrate was kept constant, and feedback of a temperature value with respect to the power was not performed. Also, in the second stage, a surface temperature of the substrate was monitored by using a radiation thermometer, and the deposition of Cu was terminated by closing the shutter of the K-cell of Cu upon confirmation of start of lowering of the temperature after a temperature rise of the substrate was stopped. Supply of Se was continued. At a time point when the vapor deposition of the second stage was terminated, the thickness of the layer formed on the substrate was increased by about 0.8 gm as compared to the time point when the vapor deposition of the first stage was terminated.

In the third stage, the shutters of the K-cells of In and Al were opened again, and In, Al, and Se were vapor-deposited on the substrate in the same manner as in the first stage. At a time point when the thickness of the layer formed on the back electrode was increased by about 0.2 μm from the time point when the vapor deposition of the third stage was started, the shutters of the K-cells of In and Ga were closed to terminate the vapor deposition of the third stage. After cooling the substrate to 300° C., the shutter of the K-cell of Se was closed to terminate the film formation of the p-type semiconductor layer.

A depth profile of the p-type semiconductor layer in an

Al/(In+Al) film thickness direction was measured and analyzed by Auger electron spectroscopy (AES). A ratio C between an Al/(In+Al) ratio A on an uppermost surface of the p-type semiconductor layer and an Al/(In+Al) ratio B at a depth exhibiting a smallest Al/(In+Al) ratio in the film was 1.110.

A solar cell of Example 12 was created in the same manner as in Example 1 except for the above-described matters.

### Examples 13 and 14 and Comparative Examples 7 and 8

In each of p-type semiconductor layer film formation steps, third stage fluxes were set to values shown in Table 3.

Solar cells of Example 13, Example 14, Comparative Example 7, and Comparative Example 8 were created in the same manner as in Example 12 except for the above-described matters.

A depth profile of each of the p-type semiconductor layers in an Al/(In+Al) film thickness direction was measured and analyzed by Auger electron spectroscopy (AES). Ratios each of which is C=A/B between an Al/(In+Al) ratio A on an uppermost surface of each of the p-type semiconductor layers and an Al/(In+Al) ratio B at a depth exhibiting a smallest Al/(In+Al) ratio in the film are shown in Table 4.

TABLE 4

| | | | | | | | | AES |
|---|---|---|---|---|---|---|---|---|
| | First stage flux | | | Third stage flux | | | | analysis |
| | P_{In1} | P_{Al1} | P₁ | P_{In3} | P_{Al3} | P₃ | | value |
| | (torr) | (torr) | (=P_{Al1}/P_{IN1}) | (torr) | (torr) | (=P_{Al3}/P_{IN3}) | P₃/P₁ | C = A/B |
| Comp. | 5.00E−07 | 5.00E−08 | 0.10 | 5.00E−07 | 4.83E−08 | 0.097 | 0.966 | 0.91 |
| Ex. 7 | | | | | | | | |
| Ex. 12 | 5.00E−07 | 5.00E−08 | 0.10 | 5.00E−07 | 5.75E−08 | 0.115 | 1.150 | 1.11 |
| Ex. 13 | 5.00E−07 | 5.00E−08 | 0.10 | 5.00E−07 | 7.25E−08 | 0.145 | 1.450 | 1.54 |
| Ex. 14 | 5.00E−07 | 5.00E−08 | 0.10 | 5.00E−07 | 8.89E−08 | 0.178 | 1.777 | 1.79 |
| Comp. | 5.00E−07 | 5.00E−08 | 0.10 | 5.00E−07 | 9.53E−08 | 0.191 | 1.905 | 2.01 |
| Ex. 8 | | | | | | | | |

### Example 15

A back electrode was formed in the same manner as in Example 1.

The back electrode (substrate) formed on the blue plate glass was placed in a sputtering device, and a precursor layer formation was performed by sputtering.

A substrate was placed in an annealing furnace, and p-type semiconductor layer formation was performed by performing a heat treatment. Hereinafter, details of the p-type semiconductor layer formation will be described.

In a sputtering step, an Ar gas (sputtering gas) was continuously supplied to a chamber, and a target formed of a Cu—Ga alloy in which a Ga content in the chamber was 25 at % was sputtered, followed by sputtering of a target formed of an In metal. Further, the Cu—Ga alloy was sputtered again. By the sputtering step, the precursor layer in which a first Cu—Ga alloy layer, an In layer, a second Cu—Ga alloy layer were stacked in this order was obtained. In the sputtering step, a thickness of the first Cu—Ga layer was 450 nm; a thickness of the In layer was 500 nm; and a thickness of the second Cu—Ga layer was 50 nm. Also, in the sputtering step, a substrate temperature was kept to 200° C., and a feed rate of the Ar gas was so set that an atmospheric pressure in the chamber was kept to 1 Pa.

In the heat treatment step after the sputtering step, selenization of the precursor layer was performed by heating the precursor layer for one hour at 550° C. under an H₂Se atmosphere to form a p-type semiconductor layer having a thickness of 2 μm.

A depth profile of the p-type semiconductor layer in a Ga/(In+Ga) film thickness direction was measured and analyzed by Auger electron spectroscopy (AES). A ratio C between a Ga/(In+Ga) ratio A on an uppermost surface of the p-type semiconductor layer and a Ga/(In+Ga) ratio B at a depth exhibiting a smallest Ga/(In+Ga) ratio in the film was 1.111.

A solar cell of Example 15 was created in the same manner as in Example 1 except for the above-described matters.

### Examples 16 and 17 and Comparative Examples 9 and 10

A back electrode was formed in the same manner as in Example 1.

The back electrode (substrate) formed on the blue plate glass was placed in a sputtering device, and a precursor layer formation was performed by sputtering.

A substrate was placed in an annealing furnace, and p-type semiconductor layer formation was performed by performing a heat treatment. Hereinafter, details of the p-type semiconductor layer formation will be described.

In a sputtering step, an Ar gas (sputtering gas) was continuously supplied to a chamber, and a target formed of a Cu—Ga alloy in which a Ga content in the chamber was 25 at % was sputtered, followed by sputtering of a target formed of an In metal. Further, the Cu—Ga alloy was sputtered again. By the sputtering step, the precursor layer in which a first Cu—Ga alloy layer, an In layer, a second Cu—Ga alloy layer were stacked in this order was obtained. Thicknesses of the first Cu—Ga alloy layer and the second Cu—Ga alloy layer in the precursor layer were the values shown in Table 4.

Solar cells of Example 16, Example 17, Comparative Example 9, and Comparative Example 10 were created in the same manner as in Example 15 except for the above-described matters.

A depth profile of each of the p-type semiconductor layers in a Ga/(In+Ga) film thickness direction was measured and analyzed by Auger electron spectroscopy (AES). Ratios each of which is C=A/B between a Ga/(In+Ga) ratio A on an uppermost surface of each of the p-type semiconductor layers and a Ga/(In+Ga) ratio B at a depth exhibiting a smallest Ga/(In+Ga) ratio in the film are shown in Table 5.

TABLE 5

| | Precursor | Precursor | Precursor | AES |
|---|---|---|---|---|
| | layer 1 CuGa | layer 2 In | layer 3 CuGa | analysis |
| | film thickness | film thickness | film thickness | value |
| | (μm) | (μm) | (μm) | C = A/B |
| Comp. | 0.45 | 0.50 | 0.05 | 0.955 |
| Ex. 9 | | | | |
| Ex. 15 | 0.40 | 0.50 | 0.10 | 1.111 |
| Ex. 16 | 0.35 | 0.50 | 0.15 | 1.443 |
| Ex. 17 | 0.30 | 0.50 | 0.20 | 1.792 |
| Comp. | 0.25 | 0.50 | 0.25 | 1.998 |
| Ex. 10 | | | | |

(Evaluation of Thin Film Solar Cell)

Characteristics of the solar cells of Examples 1 to 17 and Comparative Examples 1 to 10 are shown in Table 6.

Since an open voltage Voc is correlative with band gap energy of the light absorption layer as described in the foregoing, it is impossible to directly compare and evaluate absolute values of the open voltages in solar cells having the light absorption layers having different band gap energies, i.e. different X/(In+X) composition ratios (X is an element selected from IIIb elements except for In). Therefore, quantum efficiency measurement of each of the solar cell elements was performed, and band gap energy Eg of the light absorption layer was obtained from an absorption edge, and ΔVoc which is a value obtained by subtracting Eg and 0.6 from an open voltage value of the solar cell was calculated as indicated in Expression (3) shown below. The values of ΔVoc were compared with one another, thereby making it possible to compare and evaluate the open voltages of the solar cells having the light absorption layers having different band gap energies.

ΔVoc=Voc−Eg−0.6 (3)

Eg: Band gap energy of light absorption layer calculated from absorption edge by performing quantum efficiency measurement of solar cell

Voc: Open voltage of thin film solar cell

TABLE 6

| | | | | | | | Short-circuited | | |
|---|---|---|---|---|---|---|---|---|---|
| | P-type light | | | Composition | Open | | current density | Fill | Conversion |
| | absorption | Production | | ratio | voltage | | Jsc | factor | efficiency |
| | layer | method | P₃/P₁ | C = A/B | Voc (V) | ΔVoc | (mA/cm²) | F.F. | (%) |
| Comp. | CuInGaSe₂ | PVD | 0.988 | 0.974 | 0.605 | 0.049 | 32.0 | 0.711 | 13.7 |
| Ex. 1 | | | | | | | | | |
| Ex. 1 | CuInGaSe₂ | PVD | 1.125 | 1.288 | 0.640 | 0.100 | 32.2 | 0.725 | 14.9 |
| Ex. 2 | CuInGaSe₂ | PVD | 1.225 | 1.122 | 0.627 | 0.083 | 32.4 | 0.716 | 14.6 |
| Ex. 3 | CuInGaSe₂ | PVD | 1.375 | 1.462 | 0.633 | 0.133 | 34.0 | 0.741 | 16.0 |
| Ex. 4 | CuInGaSe₂ | PVD | 1.550 | 1.725 | 0.633 | 0.131 | 34.1 | 0.744 | 16.0 |
| Ex. 5 | CuInGaSe₂ | PVD | 1.638 | 1.561 | 0.614 | 0.113 | 34.8 | 0.763 | 16.3 |
| Comp. | CuInGaSe₂ | PVD | 1.975 | 1.950 | 0.626 | 0.030 | 31.0 | 0.696 | 13.5 |
| Ex. 2 | | | | | | | | | |
| Comp. | CuInGaS₂ | PVD | 0.975 | 1.030 | 0.660 | −0.290 | 18.5 | 0.655 | 8.0 |
| Ex. 3 | | | | | | | | | |
| Ex. 6 | CuInGaS₂ | PVD | 1.113 | 1.190 | 0.795 | −0.215 | 19.2 | 0.719 | 11.0 |
| Ex. 7 | CuInGaS₂ | PVD | 1.500 | 1.570 | 0.826 | −0.194 | 19.5 | 0.722 | 11.6 |
| Ex. 8 | CuInGaS₂ | PVD | 1.750 | 1.800 | 0.840 | −0.190 | 20.5 | 0.736 | 12.7 |
| Comp. | CuInGaS₂ | PVD | 1.963 | 1.999 | 0.760 | −0.280 | 18.6 | 0.685 | 9.7 |
| Ex. 4 | | | | | | | | | |
| Comp. | AgInGaSe₂ | PVD | 0.931 | 0.950 | 0.750 | −0.300 | 10.2 | 0.530 | 4.1 |
| Ex. 5 | | | | | | | | | |
| Ex. 9 | AgInGaSe₂ | PVD | 1.162 | 1.210 | 0.866 | −0.224 | 12.2 | 0.564 | 6.0 |
| Ex. 10 | AgInGaSe₂ | PVD | 1.538 | 1.510 | 0.890 | −0.230 | 15.8 | 0.630 | 8.9 |
| Ex. 11 | AgInGaSe₂ | PVD | 1.769 | 1.790 | 0.945 | −0.185 | 15.2 | 0.650 | 9.3 |
| Comp. | AgInGaSe₂ | PVD | 2.000 | 1.990 | 0.850 | −0.310 | 11.6 | 0.550 | 5.4 |
| Ex. 6 | | | | | | | | | |
| Comp. | CuInAlSe₂ | PVD | 0.966 | 0.910 | 0.445 | −0.005 | 28.5 | 0.555 | 7.0 |
| Ex. 7 | | | | | | | | | |
| Ex. 12 | CuInAlSe₂ | PVD | 1.150 | 1.110 | 0.525 | 0.025 | 19.9 | 0.651 | 10.2 |
| Ex. 13 | CuInAlSe₂ | PVD | 1.450 | 1.540 | 0.555 | 0.035 | 30.6 | 0.677 | 11.5 |
| Ex. 14 | CuInAlSe₂ | PVD | 1.777 | 1.790 | 0.580 | 0.040 | 31.2 | 0.690 | 12.5 |
| Comp. | CuInAlSe₂ | PVD | 1.905 | 2.010 | 0.495 | −0.085 | 26.2 | 0.590 | 7.7 |
| Ex. 8 | | | | | | | | | |
| Comp. | CuInGaSe₂ | Sputtering | — | 0.955 | 0.588 | 0.030 | 27.3 | 0.701 | 11.3 |
| Ex. 9 | | and heat | | | | | | | |
| | | treatment | | | | | | | |
| Ex. 15 | CuInGaSe₂ | Sputtering | — | 1.111 | 0.590 | 0.050 | 29.0 | 0.711 | 12.2 |
| | | and heat | | | | | | | |
| | | treatment | | | | | | | |
| Ex. 16 | CuInGaSe₂ | Sputtering | — | 1.443 | 0.601 | 0.080 | 29.2 | 0.722 | 12.7 |
| | | and heat | | | | | | | |
| | | treatment | | | | | | | |
| Ex. 17 | CuInGaSe₂ | Sputtering | — | 1.792 | 0.620 | 0.110 | 30.8 | 0.730 | 13.9 |
| | | and heat | | | | | | | |
| | | treatment | | | | | | | |
| Comp. | CuInGaSe₂ | Sputtering | — | 1.998 | 0.540 | 0.010 | 26.2 | 0.680 | 9.6 |
| Ex. 10 | | and heat | | | | | | | |
| | | treatment | | | | | | | |

It is confirmed that Examples 1 to 5 each of which is provided with the p-type light absorption layer CuInGaSe₂ which is formed by the PVD and has the value of ratio C=A/B between the Ga/(In+Ga) ratio A on the uppermost surface and the Ga/(In+Ga) ratio B at the depth exhibiting the smallest Ga/(In+Ga) ratio in the film within the range of from 1.1 to 1.8 has the larger ΔVoc and conversion efficiency as compared to Comparative Examples 1 and 2 provided with the p-type light absorption layer CuInGaSe₂ which is formed by the PVD and has the value of C out of the above-specified range.

It was confirmed that Examples 1 to 5 each of which is provided with the p-type light absorption layer CuInGaSe₂ which was produced under the conditions that the value of P₃/P₁ which is the ratio between P₃=P_{Ga3}/P_{In3} which is the ratio between the flux amounts of In and Ga in the third step and the flux ratio P₁P_{Ga1}/P_{In1} between In and Ga in the first step is within the range of from 1.1 to 1.8 in the p-type light absorption layer film formation step using the PVD has the larger ΔVoc and conversion efficiency as compared to Comparative Examples 1 and 2 provided with the p-type light absorption layer CuInGaSe₂ which is formed by the PVD and under the condition that the value of P₃/P₁ is out of the above-specified range.

It is confirmed that Examples 6 to 8 each of which is provided with the p-type light absorption layer CuInGaS₂ which is formed by the PVD and has the value of ratio C=A/B between the Ga/(In+Ga) ratio A on the uppermost surface and the Ga/(In+Ga) ratio B at the depth exhibiting the smallest Ga/(In+Ga) ratio in the film within the range of from 1.1 to 1.8 has the larger ΔVoc and conversion efficiency as compared to Comparative Examples 3 and 4 provided with the p-type light absorption layer CuInGaS₂ which is formed by the PVD and has the value of C out of the above-specified range.

It was confirmed that Examples 6 to 8 each of which is provided with the p-type light absorption layer CuInGaS₂ which was produced under the conditions that the value of P₃/P₁ which is the ratio between P₃=P_{Ga3}/P_{In3} which is the ratio between the flux amounts of In and Ga in the third step and the flux ratio P₁=P_{Ga1}/P_{In1} between In and Ga in the first step is within the range of from 1.1 to 1.8 in the p-type light absorption layer film formation step using the PVD has the larger ΔVoc and conversion efficiency as compared to Comparative Examples 3 and 4 provided with the p-type light absorption layer CuInGaS₂ which is formed by the PVD and under the condition that the value of P₃/P₁ is out of the above-specified range.

It is confirmed that Examples 9 to 11 each of which is provided with the p-type light absorption layer AgInGaSe₂ which is formed by the PVD and has the value of ratio C=A/B between the Ga/(In+Ga) ratio A on the uppermost surface and the Ga/(In+Ga) ratio B at the depth exhibiting the smallest Ga/(In+Ga) ratio in the film within the range of from 1.1 to 1.8 has the larger ΔVoc and conversion efficiency as compared to Comparative Examples 5 and 6 provided with the p-type light absorption layer AgInGaSe₂ which is formed by the PVD and has the value of C out of the above-specified range.

It was confirmed that Examples 9 to 11 each of which is provided with the p-type light absorption layer AgInGaSe₂ which was produced under the conditions that the value of P₃/P₁ which is the ratio between P₃=P_{Ga3}/P_{In3} which is the ratio between the flux amounts of In and Ga in the third step and the flux ratio P₁=P_{Ga1}/P_{In1} between In and Ga in the first step is within the range of from 1.1 to 1.8 in the p-type light absorption layer film formation step using the PVD has the larger ΔVoc and conversion efficiency as compared to Comparative Examples 5 and 6 provided with the p-type light absorption layer AgInGaSe₂ which is formed by the PVD and under the condition that the value of P₃/P₁ is out of the above-specified range.

It is confirmed that Examples 12 to 14 each of which is provided with the p-type light absorption layer CuInAlSe₂ which is formed by the PVD and has the value of ratio C=A/B between the Al/(In+Al) ratio A on the uppermost surface and the Al/(In+Al) ratio B at the depth exhibiting the smallest Al/(In+Al) ratio in the film within the range of from 1.1 to 1.8 has the larger ΔVoc and conversion efficiency as compared to Comparative Examples 7 and 8 provided with the p-type light absorption layer CuInAlSe₂ which is formed by the PVD and has the value of C out of the above-specified range.

It was confirmed that Examples 12 to 14 each of which is provided with the p-type light absorption layer CuInAlSe₂ which was produced under the conditions that the value of P₃/P₁ which is the ratio between P₃=P_{Al3}/P_{In3} which is the ratio between the flux amounts of In and Al in the third step and the flux ratio P₁=P_{Al1}/P_{In1} between In and Ga in the first step is within the range of from 1.1 to 1.8 in the p-type light absorption layer film formation step using the PVD has the larger ΔVoc and conversion efficiency as compared to Comparative Examples 7 and 8 provided with the p-type light absorption layer CuInAlSe₂ which is formed by the PVD and under the condition that the value of P₃/P₁ is out of the above-specified range.

It is confirmed that Examples 15 to 17 each of which is provided with the p-type light absorption layer CuInGaSe₂ which is formed by forming the precursor by sputtering and performing the heat treatment and has the value of ratio C=A/B between the Ga/(In+Ga) ratio A on the uppermost surface and the Ga/(In+Ga) ratio B at the depth exhibiting the smallest Ga/(In+Ga) ratio in the film within the range of from 1.1 to 1.8 has the larger ΔVoc and conversion efficiency as compared to Comparative Examples 9 and 10 provided with the p-type light absorption layer CuInGaSe₂ which is formed by forming the precursor by sputtering and performing the heat treatment and has the value of C out of the above-specified range.

### INDUSTRIAL APPLICABILITY

According to the present invention, it is possible to provide a solar cell which is capable of increasing an open voltage without deterioration of a short-circuit current as compared to conventional solar cells as well as a production method for the solar cell.

### REFERENCE SIGNS LIST

2: solar cell, 4: soda lime glass, 6: back electrode layer, 8: p-type semiconductor layer, 10: n-type semiconductor layer, 12: semi-insulation layer, 14: window layer (transparent electroconductive layer), 16: upper electrode (extraction electrode), A: Ga/(In+Ga) composition ratio on p-type semiconductor layer uppermost surface measured by Auger electron spectroscopy, and B: lowest Ga/(In+Ga) composition ratio in the film in Ga/(In+Ga) profile in a depth direction in p-type semiconductor layer, which is measured by Auger electron spectroscopy.

1. (canceled)

2. (canceled)

3. (canceled)

4. (canceled)

5. (canceled)

6. A solar cell production method comprising a p-type semiconductor production step comprising: a first step of simultaneously vapor-depositing In, an element X selected from IIIb group elements except for In, and a VIb group element; a second step of simultaneously vapor-depositing an Ib group and a VIb group; and a third step of simultaneously vapor-depositing In, the element X selected from the IIIb group elements except for In, and the VI group element again, wherein
a step in which a ratio P₃=Pₓ₃/P_{In3} between fluxes P_{In3} and Pₓ₃ of In and the element X in the third step is higher than a flux ratio P₁=Pₓ₁/P_{In1} of In and the element X in the first step.

7. The solar cell production method according to claim 6, wherein a value of a ratio P₃/P₁ between the flux ratios P₁=Pₓ₁/P_{In1} and P₃=Pₓ₃/P_{In3} of In and the element X in the first step and the third step is from 1.1 to 1.8.

8. The solar cell production method according to claim 6, wherein the IIIb group element X except for In, which is used in the first step and the third step, is Ga.

9. The solar cell production method according to claim 6, wherein the Ib group element used in the second step is Cu.

10. The solar cell production method according to claim 6, wherein the VIb group element used in the p-type semiconductor production step is one or two species selected from Se and S.

11. The solar cell production method according to claim 6, wherein the Ib group element, the element X, and the VIb group element are Cu, Ga, and Se respectively; wherein the ratio P₃=Pₓ₃/P_{In3} is 1.35 to 1.80.

12. (canceled)

13. (canceled)
